(19) United States
(12) Patent Application Publication
(10) Pub. No.: US 2008/0029872 A1
(43) Pub. Date: Feb. 7, 2008

(54) Plate structure having chip embedded therein and the manufacturing method of the same

(75) Inventors: Shih-Ping Hsu, Hsin-feng (TW); Chung-Cheng Lien, Hsin-feng (TW); Kan-Jung Chia, Hsin-feng (TW); Shang-Wei Chen, Hsin-feng (TW)

Correspondence Address: BACON & THOMAS, PLLC, 625 SLATERS LANE, FOURTH FLOOR, ALEXANDRIA, VA, 22314, US

(73) Assignee: Phoenix Precision Technology Corporation, Hsinchu (TW)

(21) Appl. No.: 11/701,442

(22) Filed: Feb. 2, 2007

(30) Foreign Application Priority Data
Aug. 7, 2006 (TW) 095128825

(51) Int. Cl. H01L 23/48; H01L 21/00

(52) U.S. Cl. 257/690; 438/125; 257/E23.01; 257/E21.001

(57) ABSTRACT

A plate structure having a chip embedded therein, comprises an aluminum oxide plate having an upper surface, a lower surface, plural aluminum channels connected to the upper surface and the lower surface, and a cavity therein; a chip embedded in the cavity, wherein the chip has an active surface; at least one electrode pad mounted on the active surface; and at least one build-up structure mounted on the surface of the aluminum oxide plate and the active surface of the chip, wherein the build-up structure comprises at least one conductive structure to electrically connect to the electrode pad. Besides, a method of manufacturing a plate structure having a chip embedded therein is disclosed.

### BACKGROUND OF THE INVENTION

1. Field of the Invention

The present invention relates to a plate structure having a chip embedded therein and the manufacturing method thereof and, more particularly, to an aluminum oxide plate having plural aluminum channels connecting thereto and chips embedded therein and the manufacturing method thereof.

2. Description of Related Art

Customer demands of the electronics industry continue to evolve rapidly and the main trends are high integration and miniaturization. In order to satisfy those requirements, especially in the packaging of semiconductor devices, development of circuit boards with the maximum of active and passive components and circuits has progressed from single to multiple layer types. This means that a greater usable area is available due to interlayer connection.

First, suitable chip package substrates of semiconductor devices are produced through a common manufacture of semiconductor package substrates. Then, the chip package substrate is processed by chip mounting, wire bounding, molding, solder ball implanting etc. for assembling semiconductor devices. Finally, the semiconductor devices having electric performance required by clients are completed. Because the steps of the practical manufacture are minute and complex, interfaces are not integrated easily at the time when manufactured by different manufacturer. Further, if the client wants to change the design of the function, efficiency and economic benefit suffer.

In the conventional semiconductor device structure, a semiconductor chip is attached on top of a substrate and then processed in wire bonding or a chip is connected to a substrate by a flip chip package. Further, solder balls are disposed on the side of the substrate that does not have semiconductor chip attached thereto so as to connect with external electronic devices. Although an objective of high quantity pin counts is achieved, too long pathways of conductive circuits making electric performances unable to be improved in the high frequent and high-speed operating condition. Otherwise, the complexity of the manufacture is relatively increased because too many connective interfaces are required for conventional packages.

In many studies, chips directly conducting to external electronic devices are embedded into package substrate to shorten conductive pathways, decrease signal loss and distortion, and increase performance of high-speed operation.

As shown in FIG. 1, a plate 101, a solder mask layer 102and a build-up structure 106 are included in the plate structure 100 having chips embedded therein. A cavity is formed on the plate 101, and the chip 102 is disposed in the cavity. The chip 102 having a plurality of electrode pads 103, and the build-up structure 106 is formed on the surface of the plate 101 and the chip 102. At least one conductive circuit 104 conducts to the plate 101 and the electrode pad 103 of the chip 102.

However, too much time is taken to prepare circuits on the surface of the plate structure conducting to the electronic devices.

In the plate structure 100 having a chip embedded therein (as shown in FIG. 1), the plate 101 could be made of ceramics due to not only good heating and mechanic characteristics due to that material preventing the plate bending, but also enable to miniaturize circuit layout and high stability of dimension. However, manufacturing costs of large size ceramics plate are very high resulting from complex steps of high-temperature sintering methods. If plates each having a chip are made of ceramic material through high-temperature sintering methods, the cost thereof would significantly be increased. Therefore, as assembling technology develops, how to decrease manufacturing costs of plates having chips, and simplify manufacturing methods are objectives to be overcome.

### SUMMARY OF THE INVENTION

In view of the above conventional shortcomings, the present invention provides a plate structure with a chip embedded therein, comprising: an aluminum oxide plate having a first surface, a second surface, plural aluminum channels, and a cavity, wherein the aluminum channels are connected to the first and second surfaces, and conductive pads are formed on the exposed terminals of the aluminum channels on the first and second surfaces; a chip embedded in the cavity with an active surface having plural electrode pads disposed thereon; and at least one build-up structure formed on the surface of the aluminum oxide plate and the active surface of the chip, wherein the build-up structure has at least one conductive structure corresponding to and conducting to the electrode pad.

In other words, in the plate structure having a chip embedded therein of the present invention, the aluminum oxide plate is an insulator, and the aluminum channels in the aluminum oxide plate are conductive channels of the first and second surfaces on the aluminum oxide plate. Therefore, in combining the plate structure and electronic devices in the present invention, manufacturing additional circuits are not required for conducting to the electronic devices. By way of conducting to the aluminum channels with the circuits, or the build-up structure on the other surface of the aluminum oxide plate, the electronic devices are conductive.

In the plate structure of the present invention, the width of the aluminum channels in the aluminum oxide plate is determined by the electrical requirements or the thickness of the plate structure, but not limited thereto. The width of the aluminum channels in the aluminum oxide plate is controlled by different oxidation or conditions, but not limited thereto.

In the plate structure of the present invention, the material of the aluminum oxide plate can be aluminum oxide or aluminum oxide alloy, but preferably is aluminum oxide alloy.

In the plate structure of the present invention, the way of forming the aluminum oxide plate can be any oxidative method, but preferably is formed by way of anodic oxidation.

The plate structure of the present invention further comprises at least one electronic device conducting to the aluminum channels and disposed on the conductive pads on the surface of the aluminum oxide plate without forming the build-up structure.

In the plate structure of the present invention, material of the electrode pads is preferably aluminum or copper, but is not limited thereto.

In the plate structure of the present invention, a fixing material is further comprised between the aluminum oxide plate and the chip to fix the chip in the cavity of the aluminum oxide plate. The fixing material is not limited to, but preferably is epoxy resin, or material of dielectric layers.

In the plate structure of the present invention, the build-up structure further comprises a dielectric layer, a circuit layer stacked up on the dielectric layer, and at least one conductive structure which penetrates the dielectric layer to provide the circuit layer conducting to the circuit layer or the electrode pad under the dielectric layer.

Material of the build-up structure is not limited to, but preferably is selected from one of a group consisting of Ajinomoto Build-up Film (ABF), bismaleimide triazine (BT), benzocyclobutene (BCB), liquid crystal polymer, polyimide (PI), poly(phenylene ether), aramide, epoxy resin, poly(tetra-fluoroethylene), and fiber glass. The material of the circuit layer and the conductive structure is not limited to, but is preferably copper, tin, nickel, chromium, titanium or copper/chromium alloy.

The plate structure of the present invention further comprises a solder mask layer as an insulating protection layer formed on the surface of the build-up structure. Openings are formed on the solder mask layer to expose the conductive pads on the surface of the build-up structure. Plural solder bumps are disposed on the openings of the solder mask layer to contact the build-up structure.

A seed layer is formed between the circuit layer and the dielectric layer, or between the conductive pads and the solder bump. The seed layer is mainly a conductive channel required for plating. The material of the seed layer is selected from any one of a group consisting of copper, tin, nickel, chromium, titanium and copper/chromium alloy. The seed layer can also be made of a conductive polymer that is selected from any one of a group consisting of polyacetylene, polyaniline, and organic sulfide polymer.

The present invention also provides a manufacturing method for a plate structure having chips therein, comprising the following steps: (A) providing an aluminum plate; (B) forming a first patterned resistive layer on the surface of the aluminum plate; (C) oxidizing the aluminum plate to form an aluminum oxide plate having a first surface, a second surface, and plural aluminum channels which connect the first and second surfaces; (D) removing the first patterned resistive layer and then forming conductive pads on the terminals of the aluminum channel exposed on the first and second surface thereof; (E) forming a cavity on the aluminum oxide plate; (F) embedding and fixing a chip into the cavity of the aluminum oxide plate, wherein the active surface of the chip has plural electrode pads; and (G) forming at least one build-up structure on the active surface of the chip and the aluminum oxide plate, wherein the build-up structure has at least one conductive structure conducting to and corresponding to the electrode pad.

Through the aforementioned way, the plate having chips embedded therein can simultaneously comprise the aluminum oxide plate (insulator), the aluminum channels (conductor) therein. The aluminum channels can be conductive channels of electronic devices while integrating with the plate having the chip and the electronic devices without additional steps being required to manufacture circuits to conduct to the electronic devices.

In the plate structure of the present invention, material of the aluminum plate can be aluminum or aluminum alloy, but is preferred to be aluminum alloy.

In the plate structure of the present invention, the oxidative method of the aluminum plate is not necessarily limited to, but preferably is anodic oxidation.

The plate structure of the present invention further comprises a step (H): disposing an electronic device conducting to the metal layer on the second surface of the aluminum plate.

In the plate structure of the present invention, the width of the aluminum channels on the aluminum plate is determined by the electrical requirements or the thickness of the plate structure, but is not limited thereto. The width of the aluminum channels in the aluminum oxide plate is controlled by different oxidation or conditions, but is not limited thereto.

In the plate structure of the present invention, the material of the aluminum pads can be aluminum or copper.

In the plate structure of the present invention, a fixing material is further formed between the aluminum oxide plate and the chip to secure the chip in the cavity of the aluminum oxide plate. The fixing material is necessarily not limited to, but preferably is epoxy resin, or material of dielectric layers.

In the manufacturing method for the plate structure of the present invention, forming the build-up structure comprises the following steps: forming a dielectric layer, on which plural vias are formed on the active surface of the chip and the aluminum oxide plate, wherein at least one via of the dielectric layer corresponds to the electrode pad of the chip; forming a seed layer on the dielectric layer and in the via of the dielectric layer; forming a resistive layer on the surface of the seed layer, wherein plural openings are formed by exposing and developing on the resistive layer, and at least one opening of the resistive layer corresponds to the electrode pad of the chip; plating an electroplating metal layer on the plural openings of the resistive layer and removing the resistive layer and the seed layer covered with the resistive layer, wherein the electroplating metal layer comprises at least one circuit layer and a conductive structure.

In the steps of the build-up structure in the present invention, a seed layer is formed before forming a patterned resistive layer, and the seed layer uncovered with the electroplating metal layer is removed after removing the patterned resistive layer. The seed layer is made of any material selected from a group consisting of copper, tin, nickel, chromium, titanium and copper/chromium alloy, but preferably copper, and wherein the seed layer is formed by one of sputtering or electroless plating. The seed layer can also be made of a conductive polymer that is formed by way of spin coating, ink-jet printing, screen printing, or imprinting, wherein the seed layer is made of selected from any one of a group consisting of polyacetylene, polyaniline, and organic sulfide polymer.

In the steps of the build-up structure in the manufacturing method for the plate with a chip in the present invention, the material of the dielectric layer is not limited to, but preferably is selected from at least any one of a group consisting of Ajinomoto Build-up Film (ABF), bismaleimide triazine (BT), benzocyclobutene (BCB), liquid crystal polymer, polyimide (PI), poly(phenylene ether), aramide, epoxy resin, poly(tetra-fluoroethylene), and fiber glass.

In the steps of the build-up structure in the manufacturing method for the plate structure with a chip in the present invention, the material of the electroplating metal layer is not necessarily limited to, but preferably is copper, tin, nickel, chromium, palladium, titanium, or alloy thereof, and more preferably is copper.

Therefore, in the plate structure with a chip and the manufacturing method thereof in the present invention, the aluminum plate (conductor) is oxidized to form an insulator through oxidation e.g. anodic oxidation. Through the first patterned resistive layer adhering on the surface of the aluminum plate to cover part surface of the aluminum plate, part of the non-oxidized aluminum (conductor) is retained to be conductive channels conducting to the second surface of the insulating plate (aluminum oxide) when oxidizing the aluminum plate. Consequently, the plate structure in the present invention comprises simultaneously an insulating ceramic plate (the aluminum oxide plate) and the conductive channel (the aluminum channel) formed by simple technology without additional steps being required to manufacture circuits to conduct to the electronic devices. Moreover, aluminum is cheap and easily manufactured to be useful to produce large quantities of the device. Hence, the aluminum oxide plate (the ceramic plate) formed by oxidation does not involve high manufacturing costs, and is beneficial to application of industry.

Other objects, advantages, and novel features of the invention will become more apparent from the following detailed description when taken in conjunction with the accompanying drawings.

### BRIEF DESCRIPTION OF THE DRAWINGS

FIG. 1 is a cross-sectional view of a conventional plate structure having a chip embedded therein;

FIGS. 2a to 2g are cross-sectional views of the manufacturing method of the plate structure in one embodiment of the present invention.

FIGS. 3a to 3c are cross-sectional views of the manufacturing method of the build-up structure in one embodiment of the present invention.

FIG. 4 is a cross-sectional view of the manufacturing method in another embodiment of the present invention.

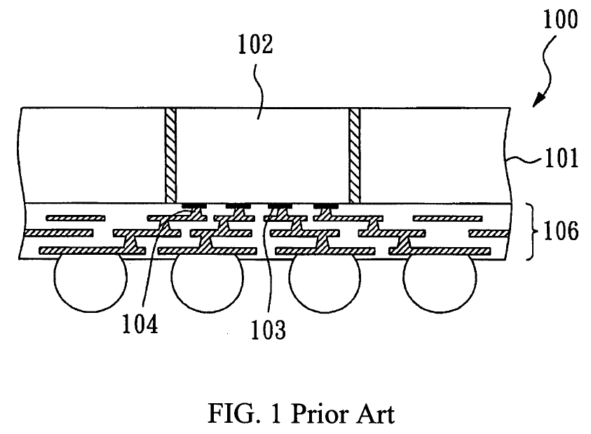

### DETAILED DESCRIPTION OF THE PREFERRED EMBODIMENT

### Embodiment 1

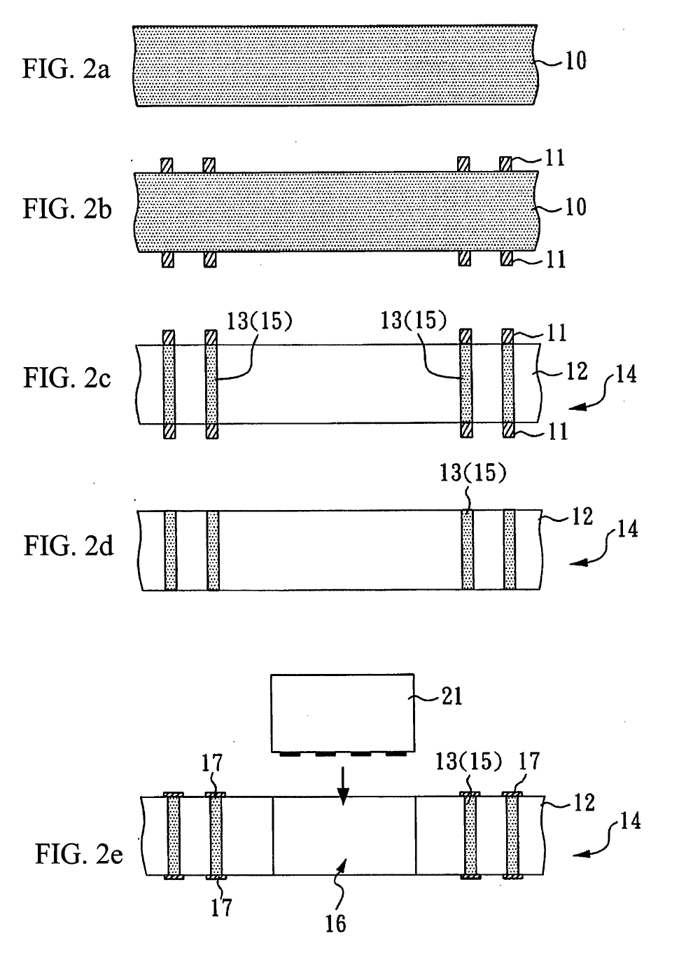

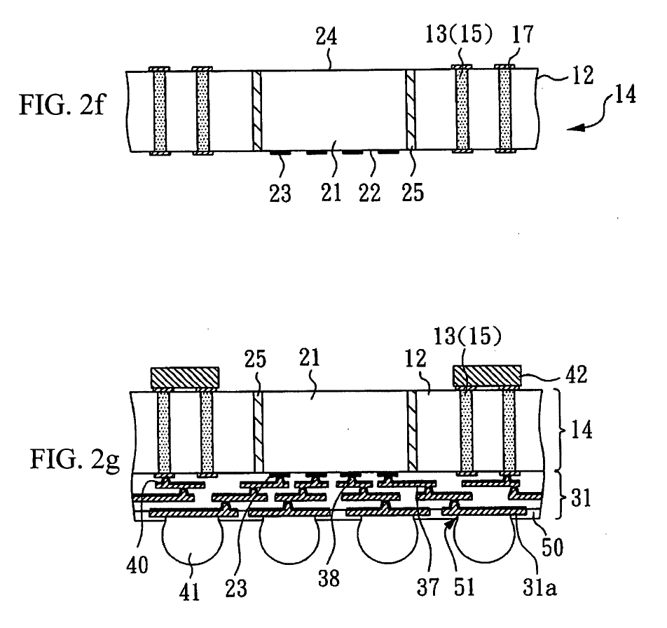

With reference to FIGS. 2a to 2g, there is shown a cross-sectional view of the manufacturing method of the plate structure having a chip in one embodiment of the present invention.

As shown in FIG. 2a, an aluminum plate 10 is first provided. Subsequently, a first patterned resistive layer 11, which is required to be adhered to the surface of the aluminum plate 10, is formed as shown in FIG. 2b.

The aluminum plate 10 is put into an electrolytic tank to perform oxidization. The part of the aluminum plate 10 not covered by the first patterned resistive layer 11 is gradually oxidized to become aluminum oxide 12 having an insulating property, but the other part of the aluminum plate 10 covered by the first patterned resistive layer 11 is still aluminum 13 having a conductive property (the structure thereof as shown in FIG. 2c). Because the aluminum part of the aluminum oxide plate 14 has to conduct to the first and the second surfaces of the aluminum oxide plate 14, an aluminum channel 15 with a conductive property is formed inside the aluminum oxide plate 14. In the present embodiment, the aluminum plate 10 with the first patterned resistive layer 11 adhered thereon is put into an electrolytic tank filled with a solution of oxalic acid or sulfuric acid to perform anodic oxidation. Through controlling the duration of anodic oxidation, and the width or the shape of the first patterned resistive layer 11, the width of the aluminum channel 15 inside the aluminum oxide layer 14 is determined.

Thus, in the present embodiment, it can be seen that the aluminum oxide plate (insulator) and the aluminum channels (conductor) therein are simultaneously completed. In other words, in the present embodiment, the insulator plate and the conductive channels between the top and the second surface of the insulator plate are formed at one time without additional steps being necessary to manufacture circuits conducting to electronic devices.

Subsequently, as shown in FIG. 2d, the first patterned resistive layer 11 on the aluminum oxide plate 14 is removed to expose the two terminals of the aluminum channel 15. Conductive pads 17 are formed on the both exposed terminals of the aluminum channel 15, as shown in FIG. 2e. The formation method of the conductive pads 17 is first to form a patterned resistive layer (not shown in figures) on the top and the second surface of the aluminum oxide plate 14. Then, after a copper layer is plated or deposited on the part not covered by the above patterned resistive layer, the above patterned resistive layer is removed. Consequently, the conductive pads 17 are completed. Because the formation method of the conductive pad 17 is conventional it is not shown in the figures. After aforementioned steps are completed, a cavity 16 is formed by a router cutting the aluminum oxide plate 14. A chip 21, which is completed by a wafer integrated circuit process and die sawing, is embedded into the cavity 16 of the aluminum oxide plate 14, and has plural electrode pads 23 made of copper attached on an active surface 22 thereof. Subsequently, the epoxy resin 25 is filled into gaps between the aluminum oxide plate 14 and the chip 21 to secure the chip 21 in the cavity 16 of the aluminum oxide plate 14, as per the structure shown in FIG. 2f. In the present embodiment, the exposed back surface 24 of the chip 21 is advantageous in providing a good heat-dissipating surface.

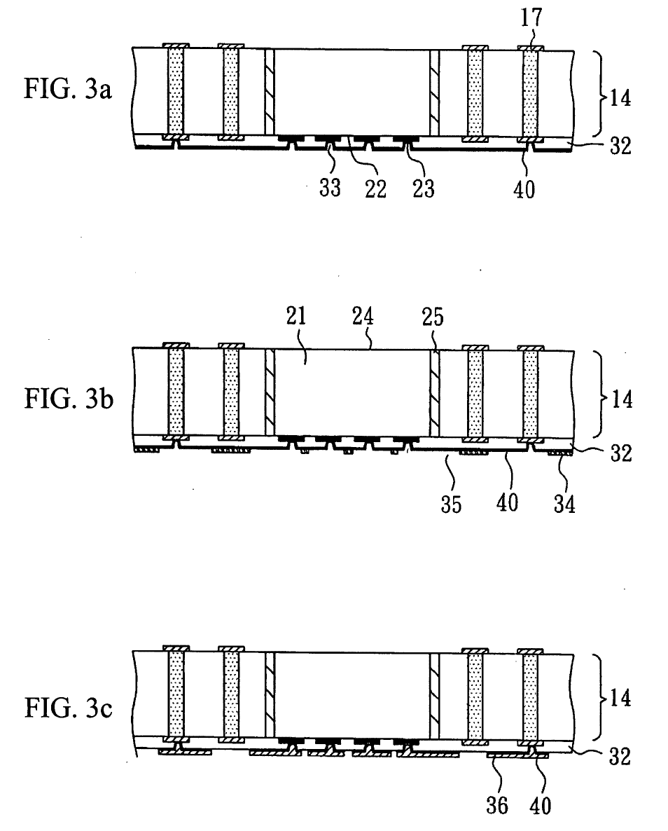

After completing the aforesaid steps, at least one build-up structure 31 is formed on the surface of the aluminum oxide plate 14 and the active surface of the chip 21, as per the structure shown in FIG. 2g. The formation method of the build-up structure 31 is shown from FIG. 3a to FIG. 3c. First, a dielectric layer 32 is formed on the surface of the aluminum oxide plate 14 and the active surface 22 of the chip 21. The material of the dielectric layer 32 is selected from any one of a group consisting of Ajinomoto Build-up Film (ABF), bismaleimide triazine (BT), benzocyclobutene (BCB), liquid crystal polymer, polyimide (PI), poly(phenylene ether), aramide, epoxy resin, poly(tetra-fluoroethylene), and fiber glass. Plural vias 33 are formed on the dielectric layer 32 through laser ablation, or exposing and developing, and at least one corresponds to the electrode pad 23 of the chip 21, as per the structure shown in FIG. 3a. If utilizing laser ablation, a de-smearing step is then performed to remove any possible residual smear due to ablation in the via of the dielectric layer. Then, a seed layer 40 is formed on the dielectric layer 32 and in the via 33 of the dielectric layer. Further, a resistive layer 34 is formed on the surface of the seed layer 40. Subsequently, plural openings 35 are formed through exposing and developing the resistive layer 34, and at least one corresponds to the electrode pad 23 of the chip 21. Finally, as shown in FIG. 3c, electroplating metal layers 36 are plated in the plural openings 35 of the resistive layer. The resistive layer 34 and the seed layer 40 covered by the electroplating metal layers 36 are removed. The build-up structure 31 shown in FIG. 2g is a multilayer structure, and is stacked up by way of build-up technology. The electroplating metal layer 36 includes a circuit layer 37 and a conductive structure 38 conducting to the electrode pad 23 of the chip 21.

As shown in FIG. 2g, a solder mask layer 50 as an insulating protection layer is formed on the surface of the build-up structure 31. Plural openings 51 are formed on the solder mask layer 50 to expose the conductive pads 31a on the surface of the build-up structure 31. Plural solder bumps 41 are disposed in the openings 51 of the solder mask layer 50, and conduct to the build-up structure 31. Electronic devices 42 are disposed on the surface of the conductive pads 17 on the aluminum oxide plate 14 to conduct to the aluminum channels 15. Thus, the plate structure having a chip embedded therein in the present embodiment is completed.

Accordingly, when integrating the electronic devices 42 on the aluminum oxide plate 14 of the present embodiment, the aluminum channel 15 can be a circuit conducting to the top and bottom surface of the aluminum oxide plate 14, and consequently the electronic devices 42 are conductive.

### Embodiment 2

The method for manufacturing a plate having a chip embedded therein of the present embodiment is very similar to the embodiment 1. Except for the step of securing the chip and the aluminum material being different from embodiment 1, everything else is approximately the same as in embodiment 1.

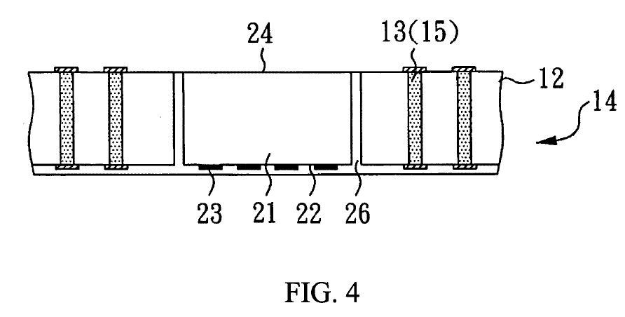

As shown in FIG. 4, after the chip 21 is embedded into the cavity of the aluminum oxide plate 14, a dielectric material layer 26 is coated on the surface of the aluminum oxide plate 14, and filled between the chip 21 and the aluminum oxide plate 14 through laminating to secure the chip 21 in the cavity of the aluminum oxide plate 14. The dielectric material layer 26 on the second surface of the aluminum oxide plate 14 can be seen as one of the dielectric layers of the build-up structure. Then, the steps of forming the build-up structure are continued. Finally, plural solder bumps are formed on the build-up structure, and the electronic devices are integrated. The plate structure having a chip embedded therein of the present embodiment is completed.

Similarly, when electronic devices of the aluminum oxide plate 14 in the present embodiment are integrated, the aluminum channel 15 can be a conductive circuit between the top and bottom of the aluminum oxide plate 14 to conduct to the electronic devices.

Although the present invention has been explained in relation to its preferred embodiment, it is to be understood that many other possible modifications and variations can be made without departing from the scope of the invention as hereinafter claimed.

What is claimed is:

1. A plate structure having a chip embedded therein comprising:
an aluminum oxide plate having a first surface, a second surface, plural aluminum channels, and a cavity, wherein the aluminum channels are connected to the first and second surfaces, and conductive pads are formed on exposed terminals of the aluminum channels on the first and second surfaces;
a chip embedded in the cavity with an active surface having plural electrode pads disposed thereon; and
at least one build-up structure formed on the surface of the aluminum oxide plate and the active surface of the chip, wherein the build-up structure has at least one conductive structure corresponding to and conducting to the electrode pad.

2. The plate structure having a chip embedded therein as claimed in claim 1, wherein the aluminum oxide plate is formed by way of anodic oxidation.

3. The plate structure having a chip embedded therein as claimed in claim 1, wherein the electrode pad is made of aluminum or copper.

4. The plate structure having a chip embedded therein as claimed in claim 1, wherein epoxy resin is filled between the aluminum oxide plate and the chip to secure the chip in the cavity of the aluminum oxide plate.

5. The plate structure having a chip embedded therein as claimed in claim 1, wherein material of a dielectric layer is filled between the aluminum oxide plate and the chip to secure the chip in the cavity of the aluminum oxide plate.

6. The plate structure having a chip embedded therein as claimed in claim 1, wherein the build-up structure comprises a dielectric layer, a circuit layer formed on the dielectric layer, and at least one conductive structure which penetrates the dielectric layer to provide the circuit layer conducting to the circuit layer or the electrode pad under the dielectric layer.

7. The plate structure having a chip embedded therein as claimed in claim 1, wherein a solder mask layer with plural openings is formed on the surface of the build-up structure, and plural solder bumps are disposed in the openings of the solder mask layer to conduct to the build-up structure.

8. The plate structure having a chip embedded therein as claimed in claim 1, further comprising at least one electronic device disposed on the conductive pads on the surface of the aluminum oxide plate without forming the build-up structure, and conducting to the aluminum channels.

9. A manufacturing method for a plate structure having a chip embedded therein comprising the following steps:
(A) providing an aluminum plate;
(B) forming a first patterned resistive layer on a surface of the aluminum plate;
(C) oxidizing the aluminum plate to form an aluminum oxide plate having a first surface, a second surface, and plural aluminum channels which connect the first and second surfaces;
(D) removing the first patterned resistive layer and then forming conductive pads on the terminal of the aluminum channel exposed on the first and second surfaces thereof;
(E) forming a cavity on the aluminum oxide plate;
(F) embedding and securing a chip into the cavity of the aluminum oxide plate, wherein the active surface of the chip has plural electrode pads; and
(G) forming at least one build-up structure on the active surface of the chip and the aluminum oxide plate.

10. The manufacturing method for the plate structure having a chip embedded therein as claimed in claim 9, wherein the aluminum oxide plate in the step (C) is formed by way of anodic oxidation.

11. The manufacturing method for the plate structure having a chip embedded therein as claimed in claim 9, wherein the electrode pad in the step (F) is made of aluminum or copper.

12. The manufacturing method for the plate structure having a chip embedded therein as claimed in claim 9, wherein epoxy resin is filled between the aluminum oxide plate and the chip in the step (F) to secure the chip in the cavity of the aluminum oxide plate.

13. The manufacturing method for the plate structure having a chip embedded therein as claimed in claim 9, wherein material of a dielectric layer is filled between the aluminum oxide plate and the chip in the step (F) to secure the chip in the cavity of the aluminum oxide plate.

14. The manufacturing method for the plate structure having a chip embedded therein as claimed in claim 9, wherein forming at least one build-up structure in the step (G) comprises the following steps:
forming a dielectric layer, where plural vias are formed, on the active surface of the chip, and the aluminum oxide plate, wherein at least one via of the dielectric layer correspond to the electrode pad of the chip;
forming a seed layer, on which a resistive layer with a plurality of openings is formed, on the dielectric layer and in the vias of the dielectric layer, wherein at least one resistive layer opening corresponds to the electrode pad of the chip;
plating an electroplating metal layer in the plural openings of the resistive layer; and
removing the resistive layer and the seed layer covered by the resistive layer, wherein the electroplating metal layer comprises at least one circuit layer and at least one conductive structure.

15. The manufacturing method for the plate structure having a chip embedded therein as claimed in claim 14, wherein material of the dielectric layer is selected from one of a group consisting of Ajinomoto Build-up Film (ABF), bismaleimide triazine (BT), benzocyclobutene (BCB), liquid crystal polymer, polyimide (PI), poly(phenylene ether), aramide, epoxy resin, poly(tetra-fluoroethylene), and fiber glass.

16. The manufacturing method for the plate structure having a chip embedded therein as claimed in claim 14, wherein the electroplating metal layer is made of copper, tin, nickel, chromium, palladium, titanium, or alloy thereof.

17. The manufacturing method for the plate structure having a chip embedded therein as claimed in claim 14, further comprising a step (H):
disposing at least one electronic devices conducting to the aluminum channel on the surface of the conductive pad without forming a build-up structure on the aluminum plate.
